(19) United States
(12) Patent Application Publication
(10) Pub. No.: US 2010/0212721 A1
(43) Pub. Date: Aug. 26, 2010

(54) THIN FILM TYPE SOLAR CELL AND METHOD FOR MANUFACTURING THE SAME

(75) Inventor: Jin Hong, Gyeonggi-do (KR)

Correspondence Address: HOSOON LEE, 9600 SW OAK ST. SUITE 525, TIGARD, OR, 97223, US

(73) Assignee: JUSUNG ENGINEERING CO., LTD., Gyeonggi-do (KR)

(21) Appl. No.: 12/673,479

(22) PCT Filed: Aug. 13, 2008
(86) PCT No.: PCT/KR2008/004696

§ 371 Date: Feb. 12, 2010

(30) Foreign Application Priority Data
Aug. 16, 2007 (KR) 10-2007-0082138

(51) Int. Cl. H01L 31/042; H01L 31/0224; H01L 31/18; H01L 31/20; H01L 31/0236; H01L 31/0368; H01L 31/0376

(52) U.S. Cl. 136/249; 438/57; 438/71; 438/97; 438/96; 257/E31.124; 257/E31.13; 257/E31.045; 257/E31.048

(57) ABSTRACT

A thin film type solar cell and a method for manufacturing the same is disclosed, wherein the thin film type solar cell is comprised of a substrate with lower and upper surfaces; a first solar cell on the upper surface of the substrate; and a second solar cell on the lower surface of the substrate, wherein a wavelength range of light absorbed into the first solar cell is different from a wave-length range of light absorbed into the second solar cell. In this case, there is no requirement for the tunneling between a first semiconductor layer of the first solar cell and a second semiconductor layer of the second solar cell, whereby the current matching is unnecessary.

### TECHNICAL FIELD

The present invention relates to a solar cell, and more particularly, to a thin film type solar cell.

### BACKGROUND ART

A solar cell with a property of semiconductor converts a light energy into an electric energy.

A structure and principle of the solar cell according to the related art will be briefly explained as follows.

The solar cell is formed in a PN-junction structure where a positive(P)-type semiconductor makes a junction with a negative(N)-type semiconductor. When a solar ray is incident on the solar cell of the PN-junction structure, holes(+) and electrons(−) are generated in the semiconductor owing to the energy of the solar ray. By an electric field generated in an PN-junction area, the holes(+) are drifted toward the P-type semiconductor, and the electrons(−) are drifted toward the N-type semiconductor, whereby an electric power is produced with an occurrence of electric potential.

The solar cell may be largely classified into a wafer type solar cell and a thin film type solar cell.

The wafer type solar cell uses a wafer made of a semiconductor material such as silicon. In the meantime, the thin film type solar cell is manufactured by forming a thin film type semiconductor on a glass substrate.

In the efficiency respect, the wafer type solar cell is better than the thin film type solar cell. However, in the case of the wafer type solar cell, it is difficult to realize a small thickness due to difficulty in performing the process. In addition, the wafer type solar cell uses a high-priced semiconductor wafer, whereby its manufacturing cost is increased.

Even though the thin film type solar cell is inferior in efficiency to the wafer type solar cell, the thin film type solar cell has advantages such as realization of thin profile and use of low-priced material. Accordingly, the thin film type solar cell is suitable for a mass production.

Hereinafter, a related art thin film type solar cell will be explained with reference to the accompanying drawings.

FIG. 1 is a cross section view illustrating a thin film type solar cell according to one type of the related art.

As shown in FIG. 1, the thin film type solar cell according to one type of the related art is comprised of a substrate 10, a front electrode layer 20, a semiconductor layer 30, and a rear electrode layer 40.

The substrate 10 is made of glass or transparent plastic. The front electrode layer 20 is made of a transparent conductive material, for example, ZnO since a solar ray is incident on the front electrode layer 20.

The semiconductor layer 30 is made of a semiconductor material such as silicon, wherein the semiconductor layer 30 is formed in a PIN structure wherein a positive semiconductor layer (hereinafter, referred to as P-layer), an intrinsic layer (hereinafter, referred to as I-layer), and a negative semiconductor layer (hereinafter, referred to as N-layer) are deposited in sequence.

The rear electrode layer 40 is made of a metal material, for example, Ag or Al. In this case, the solar ray passing through the front electrode layer 20 and the semiconductor layer 30 is reflected on the rear electrode layer 40, and is then re-incident on the semiconductor layer 30.

However, the related art thin film type solar cell of FIG. 1 can not realize high efficiency due to a low light-absorption coefficient in the semiconductor material of silicon used for the semiconductor layer 30 and due to a low light-absorption efficiency in a single PIN structure of the semiconductor layer 30 formed of a thin film with a thickness corresponding to several μm.

Accordingly, there has been proposed a solar cell with the semiconductor layer 30 formed plural PIN structures instead of the single PIN structure.

FIG. 2 is a cross section view illustrating a thin film type solar cell according to another type of the related art, wherein the thin film type solar cell is provided of dual semiconductor layers with PIN structures.

As shown in FIG. 2, the thin film type solar cell according to another type of the related art is comprised of a substrate 10, a front electrode layer 20, a first semiconductor layer 32, a buffer layer 34, a second semiconductor layer 36, and a rear electrode layer 40.

The related art thin film type solar cell of FIG. 2 includes both the first semiconductor layer 32 of PIN structure and the second semiconductor layer 36 of PIN structure. Thus, the structure of connecting the two solar cells in series can raise an open-circuit voltage of solar cell, thereby realizing the higher efficiency in comparison to that of the thin film type solar cell of FIG. 1.

Also, the buffer layer 34 made of ZnO is formed between the first semiconductor layer 32 and the second semiconductor layer 36, so as to realize the smooth drift of holes and electrodes through a tunneling junction between the first and second semiconductor layers 32 and 36.

However, the related art thin film type solar cell of FIG. 2 requires an additional step for a current matching between the first and second semiconductor layers 32 and 36. If the current matching is inaccurate due to its complicated and complex process, it is difficult to obtain the high efficiency.

For the drift of the electron generated in the first semiconductor layer 32 to the second semiconductor layer 36 in the structure of connecting the two solar cells in series, as shown in FIG. 2, it is necessary to perform a tunneling process between the first and second semiconductor layers 32 and 36. That is, the current matching is made with the maximization of tunneling.

For maximization of the tunneling, it is necessary to optimize the thickness of the buffer layer 34, and the thickness of the P-layer of the second semiconductor layer 36. This needs repetitive performances by a worker for a long period of time. Also, if the optimized vales for the thickness of the buffer layer 34 and the thickness of the P-layer of the second semiconductor layer 36 are not obtained, the current matching becomes inaccurate, so that it is difficult to realize the high-efficiency solar cell.

### DISCLOSURE OF INVENTION

### Technical Problem

Therefore, the present invention has been made in view of the above problems, and it is an object of the present invention to provide a solar cell which can realize a high efficiency without performing a step for a current matching, and a method for manufacturing the solar cell.

### Technical Solution

To achieve these objects and other advantages and in accordance with the purpose of the invention, as embodied and broadly described herein, a thin film type solar cell comprises a substrate with lower and upper surfaces; a first solar cell on the upper surface of the substrate; and a second solar cell on the lower surface of the substrate, wherein a wavelength range of light absorbed into the first solar cell is different from a wavelength range of light absorbed into the second solar cell.

At this time, the first solar cell is comprised of a first transparent electrode layer with one uneven surface, formed on the upper surface of the substrate; a first semiconductor layer on the first transparent electrode layer, wherein the first semiconductor layer includes a light-absorption layer of microcrystalline semiconductor; a first transparent conductive layer on the first semiconductor layer; and a first metal electrode layer on the first transparent conductive layer.

The first semiconductor layer is formed of a microcrystalline semiconductor layer of PIN structure. The microcrystalline semiconductor layer of PIN structure is comprised of a P-layer on the first transparent electrode layer, an I-layer on the P-layer, and an N-layer on the I-layer.

Also, the second solar cell is comprised of a second transparent electrode layer with one uneven surface, formed on the lower surface of the substrate; a second semiconductor layer under the second transparent electrode layer, wherein the second semiconductor layer includes a light-absorption layer of amorphous semiconductor; a second transparent conductive layer under the second semiconductor layer; and a second metal electrode layer under the second transparent conductive layer.

The second semiconductor layer is formed of an amorphous semiconductor layer of PIN structure. The amorphous semiconductor layer of PIN structure is comprised of an N-layer under the second transparent electrode layer, an I-layer under the N-layer, and a P-layer under the I-layer.

The second metal electrode layer is smaller in cross section area than the first metal electrode layer.

In another aspect of the present invention, a thin film type solar cell comprises a substrate; a first solar cell on one surface of the substrate, wherein the first solar cell includes a first transparent electrode layer, a first semiconductor layer comprised of a P-layer on the first transparent electrode layer, an I-layer on the P-layer, and an N-layer on the I-layer, and a first metal electrode layer deposited in sequence; and a second solar cell on the other surface of the substrate, wherein the second solar cell includes a second transparent electrode layer, a second semiconductor layer comprised of an N-layer on the second transparent electrode layer, an I-layer on the N-layer, and a P-layer on the I-layer, and a second metal electrode layer having cross section area smaller than the first metal electrode layer, deposited in sequence, wherein a bandgap in an I-layer of the first semiconductor layer is smaller than a bandgap in an I-layer of the second semiconductor layer.

In another aspect of the present invention, a thin film type solar cell comprises a substrate; a first solar cell on one surface of the substrate, wherein the first solar cell includes a first transparent electrode layer, a first semiconductor layer comprised of a P-layer on the first transparent electrode layer, an I-layer on the P-layer, and an N-layer on the I-layer, and a first metal electrode layer deposited in sequence; and a second solar cell on the other surface of the substrate, wherein the second solar cell includes a second transparent electrode layer, a second semiconductor layer comprised of an N-layer on the second transparent electrode layer, an I-layer on the N-layer, and a P-layer on the I-layer, and a second metal electrode layer having cross section area smaller than the first metal electrode layer, deposited in sequence, wherein a degree of crystallinity in an I-layer of the first semiconductor layer is higher than a degree of crystallinity in an I-layer of the second semiconductor layer.

In another aspect of the present invention, a thin film type solar cell comprises a substrate; a first solar cell on one surface of the substrate, wherein the first solar cell includes a first transparent electrode layer, a first semiconductor layer comprised of a P-layer on the first transparent electrode layer, an I-layer on the P-layer, and an N-layer on the I-layer, and a first metal electrode layer deposited in sequence; and a second solar cell on the other surface of the substrate, wherein the second solar cell includes a second transparent electrode layer, a second semiconductor layer comprised of an N-layer on the second transparent electrode layer, an I-layer on the N-layer, and a P-layer on the I-layer, and a second metal electrode layer having cross section area smaller than the first metal electrode layer, deposited in sequence, wherein the first semiconductor layer is formed of a microcrystalline semiconductor layer, and the second semiconductor layer is formed of an amorphous semiconductor layer.

At this time, Each of the first and second transparent electrode layers has one uneven surface; a first transparent conductive layer is additionally formed between the first semiconductor layer and the first metal electrode layer; and a second transparent conductive layer is additionally formed between the second semiconductor layer and the second metal electrode layer.

In another aspect of the present invention, a method for manufacturing a thin film type solar cell comprises preparing a substrate with upper and lower surfaces being opposite to each other; forming a first transparent electrode layer on the upper surface of the substrate; forming a first semiconductor layer on the first transparent electrode layer; forming a first metal electrode layer on the first semiconductor layer; forming a second transparent electrode layer on the lower surface of the substrate; forming a second semiconductor layer on the second transparent electrode layer; and forming a second metal electrode layer on the second semiconductor layer.

In another aspect of the present invention, a method for manufacturing a thin film type solar cell comprises preparing a substrate with upper and lower surfaces being opposite to each other; forming a first transparent electrode layer on the upper surface of the substrate, and a second transparent electrode layer on the lower surface of the substrate; forming a first semiconductor layer on the first transparent electrode layer; forming a first metal electrode layer on the first semiconductor layer; forming a second semiconductor layer on the second transparent electrode layer; and forming a second metal electrode layer on the second semiconductor layer.

In another aspect of the present invention, a method for manufacturing a thin film type solar cell comprises preparing a substrate with upper and lower surfaces being opposite to each other; forming a first transparent electrode layer on the upper surface of the substrate, and a second transparent electrode layer on the lower surface of the substrate; forming a first semiconductor layer on the first transparent electrode layer, and a second semiconductor layer on the second transparent electrode layer; and forming a first metal electrode layer on the first semiconductor layer, and a second metal electrode layer on the second semiconductor layer.

Further, the method includes forming a first transparent conductive layer between the first semiconductor layer and the first metal electrode layer, and a second transparent conductive layer between the second semiconductor layer and the second metal electrode layer; and performing a texturing process to the surfaces of the first and second transparent electrode layers when forming the first and second transparent electrode layers.

At this time, forming the first semiconductor layer is comprised of forming a micro-crystalline semiconductor layer of PIN structure; and forming the second semiconductor layer is comprised of forming an amorphous semiconductor layer of PIN structure.

### Advantageous Effects

Accordingly, the thin film type solar cell according to the present invention and the method for manufacturing the same have the following advantages.

First, the first solar cell is formed on the upper surface of the substrate, and the second solar cell is formed on the lower surface of the substrate. Thus, there is no requirement for the tunneling between the first semiconductor layer of the first solar cell and the second semiconductor layer of the second solar cell, whereby the current matching is unnecessary.

Accordingly, the solar ray incident on the substrate is absorbed into the first and second solar cells, whereby it enables the high efficiency of the solar cell.

Second, the texturing process is performed to the first transparent electrode layer of the first solar cell and the second transparent electrode layer of the second solar cell. As a result, both the first and second transparent electrode layers have the uneven surfaces, whereby the light-absorption efficiency is improved in the first and second semiconductor layers owing to the high light-dispersion efficiency.

Third, the first and second semiconductor layers are formed such that a light-wavelength range absorbed in the first semiconductor layer is different from a light-wavelength range absorbed in the second semiconductor layer, thereby maximizing a light-wavelength range absorbed in the semiconductor layer and improving the efficiency of solar cell.

Fourth, the second solar cell with the amorphous semiconductor layer is formed on the lower surface of the substrate corresponding to the light-incidence surface, and the first solar cell with the microcrystalline semiconductor layer is formed on the upper surface of the substrate, so that it is possible to prevent the deterioration of the thin film type solar cell.

### BRIEF DESCRIPTION OF THE DRAWINGS

FIG. 1 is a cross section view illustrating a thin film type solar cell according to one type of the related art;

FIG. 2 is a cross section view illustrating a thin film type solar cell according to another type of the related art;

FIG. 3 is a cross section view illustrating a thin film type solar cell according to one embodiment of the present invention;

FIGS. 4A to 4C are cross section views illustrating a method for manufacturing a thin film type solar cell according to one embodiment of the present invention;

FIGS. 5A to 5D are cross section views illustrating a method for manufacturing a thin film type solar cell according to another embodiment of the present invention; and

FIGS. 6A to 6E are cross section views illustrating a method for manufacturing a thin film type solar cell according to another embodiment of the present invention.

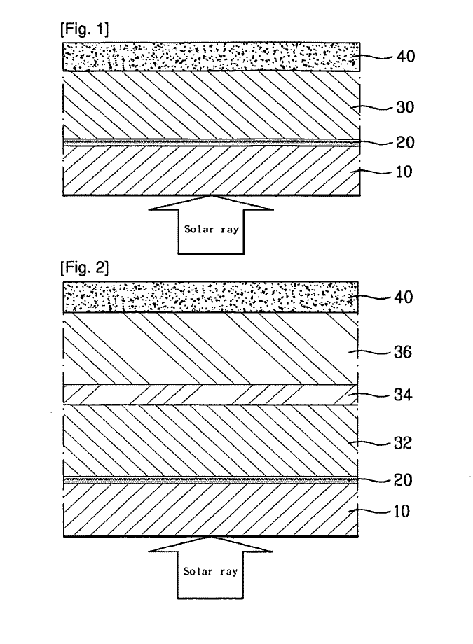

### BEST MODE FOR CARRYING OUT THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a thin film type solar cell according to the present invention and a method for manufacturing the same will be described with reference to the accompanying drawings.

### <Thin Film Type Solar Cell>

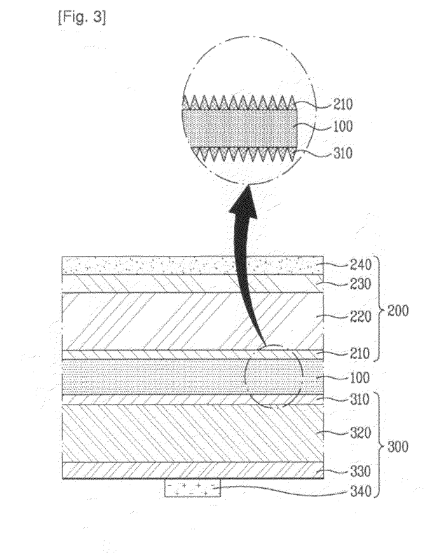

FIG. 3 is a cross section view illustrating a thin film type solar cell according to one embodiment of the present invention.

As shown in FIG. 3, the thin film type solar cell according to one embodiment of the present invention is comprised of a substrate 100, a first solar cell 200, and a second solar cell 300.

The substrate 100 includes an upper surface and a lower surface. FIG. 3 illustrates a case that solar ray is incident on the lower surface of the substrate 100.

The substrate 100 is made of glass or transparent plastic.

The first solar cell 200 is formed on the upper surface of the substrate 100, wherein the first solar cell 200 is comprised of a first transparent electrode layer 210, a first semiconductor layer 220, a first transparent conductive layer 230, and a first metal electrode layer 240.

The first transparent electrode layer 210 is formed on the upper surface of the substrate 100.

The first transparent electrode layer 210 is formed of a transparent conductive material, for example, ZnO, ZnO:B, ZnO:Al, SnO₂, SnO₂:F, or ITO (Indium Tin Oxide) by sputtering or MOCVD (Metal Organic Chemical Vapor Deposition).

Preferably, a texturing process is performed to the upper surface of the first transparent electrode layer 210. Since the first transparent electrode layer 210 corresponds to a solar-ray incidence face, it is important for the first transparent electrode layer 210 to transmit the solar ray into the inside of the solar cell with the minimized loss.

Through the texturing process, a surface of material layer is provided with an uneven surface, that is, a texture structure, by an etching process using photolithography, an anisotropic etching process using a chemical solution, or a mechanical scribing process. According as the texturing process is performed to the first transparent electrode layer 210, a solar-ray reflection ratio on the first transparent electrode layer 210 of the solar cell is decreased and a solar-ray absorbing ratio in the solar cell is increased owing to a dispersion of the solar ray, thereby improving the efficiency of solar cell.

The first semiconductor layer 220 is formed on the first transparent electrode layer 210. The first semiconductor layer 220 may be formed of a silicon-based, CuInSe ₂-based, or CdTe-based semiconductor material by a plasma-CVD method. Preferably, the first semiconductor layer 220 is formed in a PIN structure where P-layer, I-layer, and N-layer are deposited in sequence.

At this time, holes and electrons are generated in the semiconductor layer by solar rays, and the generated holes and electros are collected in the P-layer and the N-layer. For improvement of the efficiency in collection of the holes and electrons, the PIN structure is more preferable than a PN structure comprised of the P-layer and the N-layer.

If the first semiconductor layer 220 is formed in the PIN structure, depletion occurs in the I-layer by the P-layer and the N-layer, whereby an electric field is generated in the inside of the first semiconductor layer 220. That is, the holes and electrons generated by the solar ray are drifted by the electric field, and are then collected in the P-layer and the N-layer, respectively.

When forming the first semiconductor layer 220 in the PIN structure, it is preferable that the P-layer be formed on the first transparent electrode layer 210, the I-layer be formed on the P-layer, and the N-layer be formed on the I-layer in sequence. This is because a drift mobility of the hole is less than a drift mobility of the electron. In order to maximize the collection efficiency by the incident light, the P-layer is formed adjacent to the light-incidence face.

Preferably, the first and second semiconductor layers 220 and 320 are formed such that a light-wavelength range absorbed in the first semiconductor layer 220 is different from a light-wavelength range absorbed in the second semiconductor layer 320, thereby maximizing a light-wavelength range absorbed in a solar cell. More preferably, the first semiconductor layer 220 absorbs rays with a long wavelength, and the second semiconductor layer 320 absorbs rays with a short wavelength. For this, the first semiconductor layer 220 includes the I-layer (light-absorption layer) of micro-crystalline semiconductor, and the second semiconductor layer 320 includes the I-layer (light-absorption layer) of amorphous semiconductor. Accordingly, the light-absorption layer comprised of the microcrystalline semiconductor absorbs the light with the long wavelength of approximate 500 to 1100 nm, and the light-absorption layer comprised of the amorphous semiconductor absorbs the light with the short wavelength of approximate 300 to 800 nm.

Preferably, the I-layer of the first semiconductor layer 220 is smaller in its bandgap than the I-layer of the second semiconductor layer 320. Also, a degree of crystallinity in the I-layer of the first semiconductor layer 220 is higher than a degree of crystallinity in the I-layer of the second semiconductor layer 320, preferably. Accordingly, the first semiconductor layer 220 is formed of the microcrystalline semiconductor layer, and the second semiconductor layer 320 is formed of the amorphous semiconductor layer.

The reason the first and second semiconductor layers 220 and 320 are formed of the different materials will be explained in detail as follows.

First, if the first and second semiconductor layers 220 and 320 are formed of the same semiconductor material, the solar cell has limitation in the light-absorption efficiency due to the I-layer (light-absorption layer) having the same bandgap. In the meantime, if the first and second semiconductor layers 220 and 320 are formed of the different materials, it enables the high light-absorption efficiency in the solar cell with the I-layers (light-absorption layers) having the different bandgaps.

Accordingly, it is preferable that the bandgap in the I-layer of the first semiconductor layer 220 be different from the bandgap in the I-layer of the second semiconductor layer 320. In order to provide the different bandgaps in the first and second semiconductor layers 220 and 320, the I-layer of the first semiconductor layer 220 and the I-layer of the second semiconductor layer 320 are different in a degree of crystallinity. In more detail, any one of the first and second semiconductor layers 220 and 320 may be formed of the microcrystalline semiconductor layer, and the other may be formed of the amorphous semiconductor layer.

Next, if an amorphous semiconductor material is exposed to the light for a long period of time, it may accelerate the deterioration of amorphous semiconductor material. If the amorphous semiconductor material is provided on the light-incidence face, and the microcrystalline semiconductor material is provided on its opposite surface, it is possible to decrease the deterioration of the solar cell. Accordingly, the second semiconductor layer 320, provided on the lower surface of the substrate 100 where the solar ray is incident, is preferably formed of the amorphous semiconductor material. In the meantime, the first semiconductor layer 220, provided on the upper surface of the substrate 100, is preferably formed of the microcrystalline semiconductor material. Thus, it is preferable that the degree of crystallinity in the I-layer of the first semiconductor layer 220 be higher than the degree of crystallinity in the I-layer of the second semiconductor layer 320.

The microcrystalline semiconductor material has the bandgap of 1.1 eV, and the amorphous semiconductor material has the bandgap of 1.7˜1.8 eV. Preferably, the bandgap of the I-layer of the first semiconductor layer 220 is smaller than the bandgap of the I-layer of the second semiconductor layer 320.

The first transparent conductive layer 230 is formed on the first semiconductor layer 220.

The first transparent conductive layer 230 is formed of a transparent conductive material, for example, ZnO, ZnO:B, ZnO:Al, or Ag by sputtering or MOCVD (Metal Organic Chemical Vapor Deposition), wherein the first transparent conductive layer 230 has a thickness of 500 to 10000 Å.

The first transparent conductive layer 230 may be omitted. To improve the efficiency of the solar cell, it is preferable that the first transparent conductive layer 230 be provided. That is, if forming the first transparent conductive layer 230, the solar ray is dispersed at different angles, thereby raising the ratio of light which is reflected on the first metal electrode layer 240 and is re-incident on the solar cell.

The first metal electrode layer 240 is formed on the first transparent conductive layer 230.

The first metal electrode layer 240 may be formed of a metal material such as Ag,

Al, Ag+Mo, Ag+Ni, or Ag+Cu by sputtering or printing.

The second solar cell 300 is formed on the lower surface of the substrate 100, wherein the second solar cell 300 is comprised of a second transparent electrode layer 310, a second semiconductor layer 320, a second transparent conductive layer 330, and a second metal electrode layer 340.

The second transparent electrode layer 310 is formed on the lower surface of the substrate 100.

The second transparent electrode layer 310 is formed of the same material as that of the first transparent electrode layer 210, that is, the transparent conductive material such as ZnO, ZnO:B, ZnO:Al, SnO₂, SnO₂:F, or ITO (Indium Tin Oxide) by sputtering or MOCVD (Metal Organic Chemical Vapor Deposition). Preferably, a texturing process is performed to the lower surface of the second transparent electrode layer 310, thereby forming the uneven lower surface of the second transparent electrode layer 310.

The second semiconductor layer 320 is formed under the second transparent electrode layer 310.

The second semiconductor layer 320 is formed of a semiconductor material of a silicon-based, CuInSe ₂-based, or CdTe-based semiconductor material by a plasma-CVD method. Preferably, the semiconductor material is formed in a PIN structure where P-layer, I-layer and N-layer are deposited in sequence.

If the second semiconductor layer 320 is formed in the PIN structure, it is necessary to position the P-layer adjacent to the light-incidence face. For this, the N-layer is formed under the second transparent electrode layer 310, the I-layer is formed under the N-layer, and the P-layer is farmed under the I-layer.

As mentioned above, the second semiconductor layer 320 absorbs the light with the short wavelength. For this, the second semiconductor layer 320 includes the I-layer (light-absorption layer) comprised of the amorphous semiconductor material.

Also, the bandgap in the I-layer of the second semiconductor layer 320 is larger than the bandgap in the I-layer of the first semiconductor layer 220, preferably. Also, the degree of crystallinity in the I-layer of the second semiconductor layer 320 is lower than the degree of crystallinity in the I-layer of the first semiconductor layer 220, preferably. Accordingly, the second semiconductor layer 320 is formed of the amorphous semiconductor layer, and the first semiconductor layer 220 is formed of the microcrystalline semiconductor layer, preferably.

The second transparent conductive layer 330 is formed under the second semiconductor layer 320.

The second transparent conductive layer 330 is formed of the same material as that of the first transparent conductive layer 230. For example, the second transparent conductive layer 330 is formed of a transparent conductive material such as ZnO, ZnO:B, ZnO:Al, or Ag by sputtering or MOCVD (Metal Organic Chemical Vapor Deposition). In this case, the second transparent conductive layer 330 has a thickness of 500 to 10000 Å, preferably. The second transparent conductive layer 330 may be omitted at needed.

The second metal electrode layer 340 is formed under the second transparent conductive layer 330.

The second metal electrode layer 340 may be firmed of a metal material such as Ag,

Al, Ag+Mo, Ag+Ni, or Ag+Cu.

In the meantime, since the solar ray is incident on the lower surface of the substrate 100, the minimized cross-section area of the second metal electrode layer 340 enables the increase of light-incidence amount. Accordingly, the cross-section area of the second metal electrode layer 340 is smaller than the cross-section area of the first metal electrode layer 240. For this, a thin film may be firstly formed by sputtering, and then the thin film is patterned by etching. In another aspect, a predetermined pattern may be directly formed by a screen printing method, an inkjet printing method, a gravure printing method, or a micro-contact printing method.

In the case of the screen printing method, a material is transferred to a predetermined body through the use of a screen and a squeeze. The inkjet printing method sprays a material onto a predetermined body through the use of an inkjet, to thereby form a predetermined pattern thereon. In the case of the gravure printing method, a material is coated on an intaglio plate, and then the coated material is transferred to a predetermined body, thereby forming a predetermined pattern on the predetermined body. The micro-contact printing method forms a predetermined pattern of material on a predetermined body through the use of a predetermined mold.

The solar cell according to the present invention is provided with the first and second solar cells 200 and 300 which are operated separately. Also, the solar ray with the long wavelength is absorbed in the first semiconductor layer 220 of the microcrystalline semiconductor for the first solar cell 200, and the solar ray with the short wavelength is absorbed in the second semiconductor layer 320 of the amorphous semiconductor for the second solar cell 300. Since a tunneling is not formed between the first semiconductor layer 220 of the first solar cell 200 and the second semiconductor layer 320 of the second solar cell 300, there is no requirement for a current matching.

In the case of the thin film type solar cell according to the present invention, as shown in FIG. 3, the solar ray is incident on the rear surface of the substrate 100. If the solar ray is incident on the upper surface of the substrate 100, the position of the first and second solar cells 200 and 300 is opposite to the position of the first and second solar cells 200 and 300 shown in FIG. 3.

### <Method for Manufacturing Thin Film Type Solar Cell>

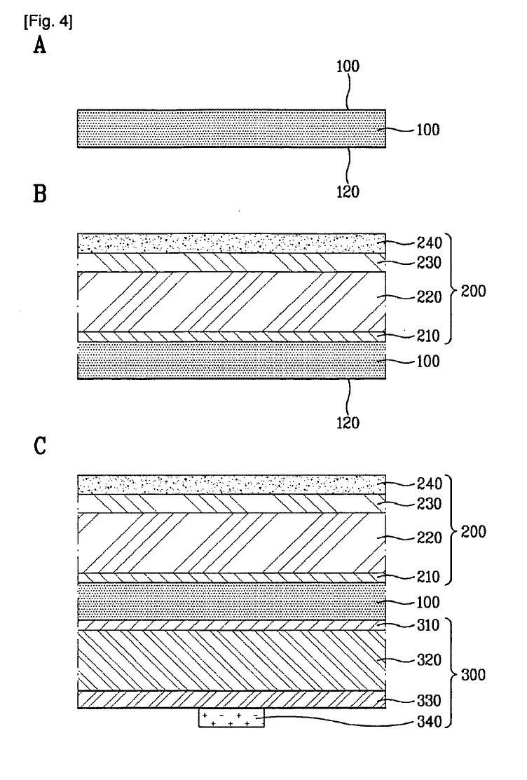

FIGS. 4A to 4C are cross section views illustrating a method for manufacturing a thin film type solar cell according to one embodiment of the present invention.

As shown in FIG. 4A, a substrate 100 is prepared, which is provided with a first surface 110 and a second surface 120 being opposite to each other. The substrate 100 may be made of glass or transparent plastic.

Referring to FIG. 4B, a first solar cell 200 is formed on the first surface 110 of the substrate 100.

A process for forming the first solar cell 200 includes steps of forming a first transparent electrode layer 210 on the first surface of the substrate 100; forming a first semiconductor layer 220 on the first transparent electrode layer 210; forming a first transparent conductive layer 230 on the first semiconductor layer 220; and forming a first metal electrode layer 240 on the first transparent conductive layer 230.

In this case, a process for forming the first transparent electrode layer 210 may be performed by a sputtering method or MOCVD (Metal Organic Chemical Vapor Deposition) with a transparent conductive material such as ZnO, ZnO:B, ZnO:Al, SnO₂, SnO₂:F, or ITO (Indium Tin Oxide).

When forming the first transparent electrode layer 210, a texturing process may be performed thereto so as to obtain an uneven surface of the first transparent electrode layer 210. For example, the texturing process may include an etching process using photolithography, an anisotropic etching process using a chemical solution, or a mechanical scribing.

The first semiconductor layer 220 may be formed of a silicon-based, CuInSe ₂-based, or CdTe-based microcrystalline semiconductor material by a plasma-CVD method, wherein the first semiconductor layer 220 may have a PIN structure where P-layer, I-layer and N-layer are deposited in sequence.

A process for forming the first transparent conductive layer 230 may be performed by a sputtering method or MOCVD (Metal Organic Chemical Vapor Deposition) with a transparent conductive material such as ZnO, ZnO:B, ZnO:Al, or Ag. In this case, the first transparent conductive layer 230 has a thickness of 500 to 10000 Å.

A process for forming the first metal electrode layer 240 may be performed by a sputtering or printing method with a metal material such as Ag, Al, Ag+Mo, Ag+Ni, or Ag+Cu.

As the substrate 100 is turned over, the second surface 120 of the substrate 100 faces upward. After that, the second solar cell 300 is formed on the second surface 120 of the substrate 100, to thereby complete the thin film type solar cell of FIG. 4C.

A process for forming the second solar cell 300 includes steps of forming a second transparent electrode layer 310 on the second surface 120 of the substrate 100; forming a second semiconductor layer 320 on the second transparent electrode layer 310; forming a second transparent conductive layer 330 on the second semiconductor layer 320; and forming a second metal electrode layer 340 on the second transparent conductive layer 330.

A process for forming the second transparent electrode layer 310 may be performed by a sputtering method or MOCVD (Metal Organic Chemical Vapor Deposition) with a transparent conductive material such as ZnO, ZnO:B, ZnO:Al, SnO₂, SnO₂:F, or ITO (Indium Tin Oxide).

A process for forming the second transparent electrode layer 310 may includes a texturing process to realize an uneven surface of the second transparent electrode layer 310.

A process for forming the second semiconductor layer 320 may be performed by a plasma-CVD method with a silicon-based, CuInSe ₂-based, or CdTe-based amorphous semiconductor material. At this time, the second semiconductor layer 320 is formed in a PIN structure where N-layer, I-layer and P-layer are deposited in sequence.

A process for forming the second transparent conductive layer 330 may be performed by a sputtering method or MOCVD (Metal Organic Chemical Vapor Deposition) with a transparent conductive material such as ZnO, ZnO:B, ZnO:Al, or Ag. In this case, the second transparent conductive layer 330 has a thickness of 500 to 10000 Å.

In order to form the second metal electrode layer 340, a metal thin film of Ag, Al, Ag+Mo, Ag+Ni, or Ag+Cu is firstly formed by sputtering or printing, and is then patterned by etching. In another method, a predetermined pattern may be directly formed by a screen printing method, an inkjet printing method, a gravure printing method, or a micro-contact printing method.

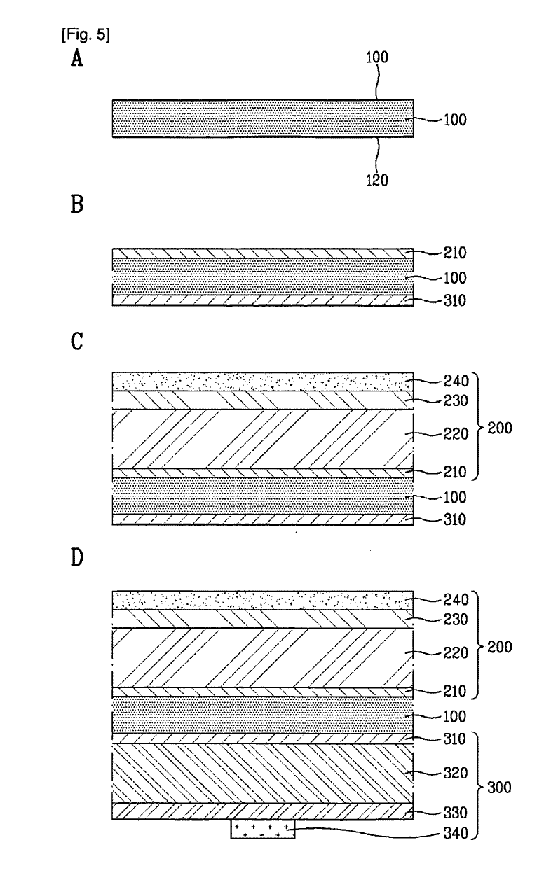

FIGS. 5A to 5D are cross section views illustrating a method for manufacturing a thin film type solar cell according to another embodiment of the present invention, wherein the material of each layer and the process of forming each layer are same as FIGS. 4A to 4C, whose detailed explanation will be omitted.

First, as shown in FIG. 5A, the substrate 100 is prepared, which includes the first and second surfaces 110 and 120 being opposite to each other.

As shown in FIG. 5B, the first transparent electrode layer 210 is formed on the first surface 110 of the substrate 100, and the second transparent electrode layer 310 is formed on the second surface 120 of the substrate 100. In more detail, after forming the first transparent electrode layer 210 on the first surface 110 of the substrate 100, the substrate 100 is turned over so that the second surface 120 of the substrate 100 faces upward. Then, the second transparent electrode layer 310 is formed on the second surface 120 of the substrate 100.

As shown in FIG. 5C, the first semiconductor layer 220 is formed on the first transparent electrode layer 210. The first transparent conductive layer 230 is formed on the first semiconductor layer 220, and the first metal electrode layer 240 is formed on the first transparent conductive layer 230, thereby completing the first solar cell 200.

As shown in FIG. 5D, the second semiconductor layer 320 is formed on the second transparent electrode layer 310, and the second transparent conductive layer 330 is formed on the second semiconductor layer 320. Then, the second metal electrode layer 340 is formed on the second transparent conductive layer 330, thereby completing the second solar cell 300.

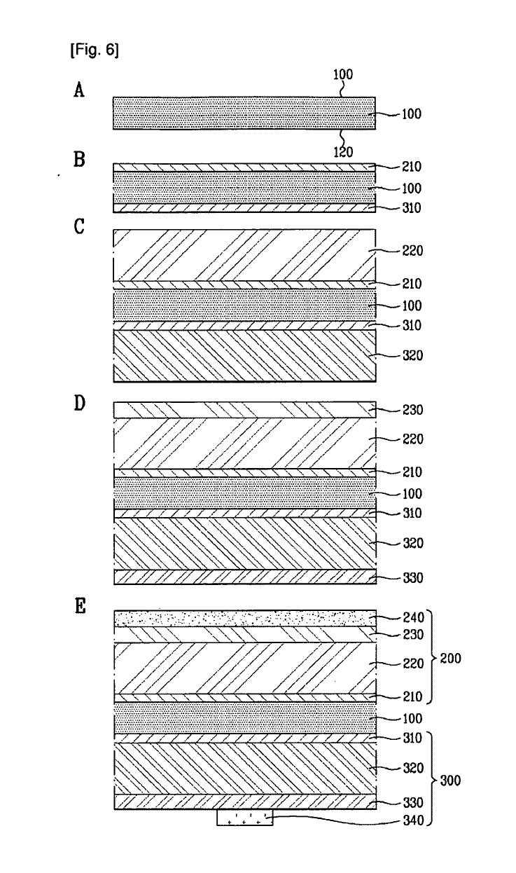

FIGS. 6A to 6E are cross section views illustrating a method for manufacturing a thin film type solar cell according to another embodiment of the present invention, wherein the material of each layer and the process of forming each layer are same as FIGS. 4A to 4C, whose detailed explanation will be omitted.

First, as shown in FIG. 6A, the substrate 100 is prepared, which includes the first and second substrates 110 and 120 being opposite to each other.

As shown in FIG. 6B, the first transparent electrode layer 210 is formed on the first surface 110 of the substrate 100, and the second transparent electrode layer 310 is formed on the second surface 120 of the substrate 100. This process may be performed by forming the first transparent electrode layer 210 on the first surface 110 of the substrate 100; turning over the substrate 100 so as to make the second surface 120 face upward; and forming the second transparent electrode layer 310 on the second surface 120 of the substrate 100.

As shown in FIG. 6C, the first semiconductor layer 220 is formed on the first transparent electrode layer 210, and the second semiconductor layer 320 is formed on the second transparent electrode layer 310. This process may be performed by forming the first semiconductor layer 220 on the first transparent electrode layer 210; turning over the substrate 100 so as to make the second surface 120 face upward; and forming the second semiconductor layer 320 on the second transparent electrode layer 310.

As shown in FIG. 6D, the first transparent conductive layer 230 is formed on the first semiconductor layer 220, and the second transparent conductive layer 330 is formed on the second semiconductor layer 320. This process may be performed by forming the first transparent conductive layer 230 on the first semiconductor layer 220; turning over the substrate 100 so as to make the second surface 120 face upward; and forming the second transparent conductive layer 330 on the second semiconductor layer 320.

As shown in FIG. 6E, the first metal electrode layer 240 is formed on the first transparent conductive layer 230, and the second metal electrode layer 340 is formed on the second transparent conductive layer 330, thereby completing the first and second solar cells 200 and 300. This process may be performed by forming the first metal electrode layer 240 on the first transparent conductive layer 230; turning over the substrate 100 so as to make the second surface 120 face upward; and forming the second metal electrode layer 340 on the second transparent conductive layer 330.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A thin film type solar cell comprising:
a substrate with lower and upper surfaces;
a first solar cell including a silicon-based semiconductor layer, the first solar cell on the upper surface of the substrate; and
a second solar cell including a silicon-based semiconductor layer, the second solar cell under the lower surface of the substrate,
wherein a wavelength range of light absorbed into the first solar cell is different from a wavelength range of light absorbed into the second solar cell.

2. The thin film type solar cell according to claim 1, wherein the first solar cell comprises:
a first transparent electrode layer formed on the upper surface of the substrate;
a first semiconductor layer on the first transparent electrode layer, wherein the first semiconductor layer includes a light-absorption layer of microcrystalline semiconductor;
a first transparent conductive layer on the first semiconductor layer; and
a first metal electrode layer on the first transparent conductive layer.

3. The thin film type solar cell according to claim 2, wherein the first transparent electrode layer has one uneven surface.

4. The thin film type solar cell according to claim 2, wherein the
first transparent electrode layer and the
first transparent conductive layer are formed of a material containing ZnO, or ZnO doped with a group III element in the periodic table.

5. The thin film type solar cell according to claim 2, wherein the first semiconductor layer includes a P-layer of microcrystalline semiconductor layer, and an N-layer microcrystalline semiconductor layer.

6. The thin film type solar cell according to claim 5, wherein the first semiconductor layer includes the P-layer on the first transparent electrode layer; an I-layer of semiconductor material on the P-layer; and the N-layer on the I-layer.

7. The thin film type solar cell according to claim 1, wherein the second solar cell comprises;
a second transparent electrode layer on the lower surface of the substrate;
a second semiconductor layer under the second transparent electrode layer, wherein the second semiconductor layer includes a light-absorption layer of amorphous semiconductor;
a second transparent conductive layer under the second semiconductor layers; and
a second metal electrode layer under the second transparent conductive layer.

8. The thin film type solar cell according to claim 7, wherein the second transparent electrode layer has one uneven surface.

9. The thin film type solar cell according to claim 7, wherein the second transparent electrode layer and the second transparent conductive layer are formed of a material containing ZnO, or ZnO doped with a group III element in the periodic table.

10. The thin film type solar cell according to claim 7, wherein second semiconductor layer includes a P-layer of amorphous semiconductor material, and an N-layer of amorphous semiconductor material.

11. The thin film type solar cell according to claim 10, wherein the second semiconductor layer includes the N-layer under the second transparent electrode layer; and I-layer of semiconductor layer under the N-layer; and the P-layer under the I-layer.

12. A thin film type solar cell comprising:
a substrate;
a first solar cell on one surface of the substrate, wherein the first solar cell includes a first transparent electrode layer, a first semiconductor layer, and a first metal electrode layer formed in sequence; and
a second solar cell on the other surface of the substrate, wherein the second solar cell includes a second transparent electrode layer, a second semiconductor layer, and a second metal electrode layer formed in sequence;
wherein the first and second semiconductor layers each include a P-layer of silicon-based semiconductor material and an N-layer of silicon-based semiconductor material; and
wherein the first and second transparent electrode layers each are formed of a material containing ZnO, or ZnO doped with a group III element in the periodic table.

13. The thin film type solar cell according to claim 12,
wherein each of the first and second semiconductor layers includes an I-layer of semiconductor material; and
wherein a bandgap in the I-layer of the first semiconductor layer is smaller than a bandgap in the I-layer of the second semiconductor layer.

14. The thin film type solar cell according claim 12,
wherein each of the first and second semiconductor layers includes an I-layer of semiconductor material; and
wherein a degree of crystallinity in the I-layer of the first semiconductor layer is higher than a degree of crytallinity in the I-layer of the second semiconductor layer.

15. The thin film type solar cell according to claim 12,
wherein each of the first and second semiconductor layers includes an I-layer of semiconductor material; and wherein the first semiconductor layer is formed of a microcrystalline semiconductor material, and the second semiconductor layer is formed of an amorphous semiconductor material.

16. The thin film type solar cell according to claim 12, thin film type solar
wherein the first semiconductor layer includes a P-layer of semiconductor material on one surface of the first transparent electrode laver, an I-layer of semiconductor material on the P-layer, and an N-layer of semiconductor material on the I-layer; and
wherein the second semiconductor layer includes an N-layer of semiconductor material on one surface of the second transparent electrode layer, an I-laver of semiconductor material on the N-layer, and a P-layer of semiconductor material on the I-layer.

17. The thin film type solar cell according to claim 12,
wherein each of the first and second transparent electrode layers has one uneven surface; and
wherein a first transparent conductive layer is additionally formed between the first semiconductor layer and the first metal electrode layer, and a second transparent conductive layer is additionally formed between the second semiconductor layer and the second metal electrode layer.

18. The thin film type solar cell according to claim 12, wherein a cross-section area in the second metal electrode layer is smaller than a cross-section area in the first metal electrode layer.

19. A method for manufacturing a thin film type solar cell comprising:
preparing a substrate with upper and lower surfaces,
forming a first transparent electrode layer on one surface of the substrate;
forming a first semiconductor layer on the first transparent electrode layer;
forming a first metal electrode layer on the first semiconductor layer;
forming a second transparent electrode layer on the other surface of the substrate;
forming a second semiconductor layer on the second transparent electrode layer; and
forming a second metal electrode layer on the second semiconductor layer,
wherein the first and second semiconductor layers respectively include a P-layer of silicon-based semiconductor material and an N-layer of silicon-based semiconductor material; and
wherein the first and second transparent electrode layers are formed of a conductive material containing ZnO, or ZnO doped with a group of III element in the periodioc table by sputtering or Metal Organic Chemical Vapor Deposition.

20. The method according to claim 19, further comprising:
forming a first transparent conductive layer between the first semiconductor layer and the first metal electrode layer;
forming a second transparent conductive layer between the second semiconductor layer and the second metal electrode layer; and
performing a texturing process to the surfaces of the first and second transparent electrode layers when forming the first and second transparent electrode layers.

21. The method according to claim 20,
wherein the first and second transparent conductive layers are formed of a conductive material containing ZnO, or ZnO doped with a group III element in the periodic table by sputtering or Metal Organic Chemical Vapor Deposition

22. The method according to claim 19, wherein forming the first semiconductor layer comprises forming a microcrystalline semiconductor layer of PIN structure; and forming the second semiconductor layer comprises forming an amorphous semiconductor layer of PIN structure.
